(19) United States
(12) Patent Application Publication
(10) Pub. No.: US 2009/0032083 A1
(43) Pub. Date: Feb. 5, 2009

(54) Solar Collection Device

(76) Inventors: Jerry B. Torrance, Portola Valley, CA (US); Robert J. Pressley, San Francisco, CA (US)

Correspondence Address: T H P Richardson, 1055 Trinity Drive, Menlo Park, CA, 94025, US

(21) Appl. No.: 11/991,986

(22) PCT Filed: Sep. 13, 2006
(86) PCT No.: PCT/US2006/035986

§ 371 Date: Mar. 13, 2008

Related U.S. Application Data
(60) Provisional application No. 60/717,321, filed on Sep. 15, 2005.

(51) Int. Cl. H01L 31/02

(52) U.S. Cl. 136/246

(57) ABSTRACT

Solar collection devices make use of (a) an absorption body including luminescent material and (b) photovoltaic (PV) cells placed at the edges of the absorption body. The luminescent material absorbs solar radiation and generates luminescent radiation of a different wavelength. The PV cells receive the luminescent radiation and convert it into electrical energy. The devices have one or more of the following characteristics:—(a) the luminescent material is such that part of the radiation is converted into electrical energy and part of the radiation is transmitted; (b) the PV cells are bifacial, i.e. will generate electricity in response to radiation from both sides; (c) the PV cells have electrodes which do not lie between the PV cell and the luminescent body; and (d) the constitution and/or dimensions of the PV cells and/or of the luminescent body are selected so as to provide a desired result, e.g. a desired spatial variation in the generation of luminescent radiation, a desired spatial variation in the ratio of absorption to transmission, or more uniform generation of current in the different PV cells.

### CROSS-REFERENCE TO RELATED APPLICATION

This application claims priority from U.S. provisional application No. 60/717,321, filed 15 Sep., 2005. The entire disclosure of that application is incorporated herein by reference for all purposes.

### BACKGROUND OF THE INVENTION

1. Field of the Invention

This invention relates to solar collection devices.

2. Introduction to the Invention

In the direct conversion of solar radiation into electrical energy by photovoltaic (PV) cells, the efficiency depends in part on the orientation of the cells to the radiation. An alternative method, which is less dependent on orientation, is to absorb the solar radiation by luminescent material forming part of a body which has PV cells at its periphery. In this specification, this alternative method is referred to as the “luminescent method” and the body containing luminescent material is referred to as the “luminescent body”. The luminescent material absorbs solar radiation and generates luminescent radiation of a different wavelength. A substantial proportion of the luminescent radiation, after internal reflections, is received by the PV cells and converted into electrical energy. The costs of the luminescent method, per unit of generated electrical energy, are less than for direct conversion. The objective of both methods is to convert as much as possible of the solar radiation into electrical energy. For further details of the luminescent method, reference may be made, for example, to U.S. Pat. Nos. 6,476,312, 5,816,238, 4,661,649, 4,644,716, 4,618,694, 4,488,047, 4,379,613, 4,329,535, 4,227,939, 4,149,902, 4,127,425 and 4,110,123. The entire disclosure of each of those United States patents is incorporated herein by reference all purposes.

### SUMMARY OF INVENTION

We have realized, in accordance with the present invention, that the luminescent method outlined above can advantageously be modified in one or more of the following ways:—
(a) The method is designed so that a part of the solar radiation is converted into luminescent radiation, and another part of the radiation is transmitted—this can be done, for example, by (a) selection of the luminescent materials in the luminescent body, and/or (b) making use of a plurality of luminescent bodies having different absorption characteristics, these expedients, either alone or together, optionally being used in conjunction with bodies which transmit or absorb substantially all the solar radiation, for example clear glass panels or conventional direct-conversion PV cells.
(b) At least some of the PV cells at the edges of the luminescent bodies are bifacial (i.e. have two faces, generally faces which are opposite to each other, each of which will generate electricity in response to luminescent and/or other radiation)—this is, for example, useful when a PV cell is placed between two luminescent bodies.
(c) At least some of the PV cells at the edges of the luminescent bodies have electrodes which do not cover any substantial part of the face of the PV cell which receives luminescent radiation.
(d) The luminescent body (or, if there is a plurality of luminescent bodies, at least one of the luminescent bodies, or the combination of the luminescent bodies) is constructed and arranged so as to provide a desired result, for example, in the amount, and/or the wavelength, and/or the location (across the plane of the luminescent body and/or at right angles to the plane of the luminescent body) of the radiation which is converted into luminescent radiation and/or which is transmitted. One example of such a result is greater uniformity in the amount of the luminescent radiation received by different PV cells, for example so that the current generated by each of the PV cells, when the conversion body is uniformly illuminated, is not more than 1.5 times, preferably not more than 1.3 times, particularly not more than 1.1 times, the smallest amount of current generated by any of the PV cells.
   Expedients for achieving a desired result include, for example, one or more of—
      (i) The luminescent material is non-uniformly distributed at right angles to the plane of the luminescent body (i.e. through the thickness of the luminescent body), for example so that at least 50%, preferably at least 75%, for example at least 90%, of the luminescent material lies in a layer or layers constituting at most 30%, for example at least 15%, of the thickness of the body, for example in a first layer providing the first principal surface of the luminescent body and/or in a second layer providing the second principal surface of the body.
      (ii) The luminescent material is non-uniformly distributed across the plane of the luminescent body, for example so that at least 50%, preferably at least 75%, for example at least 90%, of the luminescent material lies in a area or areas constituting at most 30%, for example at most 15%, of the area of the body.
      (iii) The shape of the luminescent body is a triangle, a square, or other regular polyhedron, or a rectangle, or a shape which comprises regular or irregular curves, e.g. a circle or an ellipse, making use of flexible PV cells.
(e) The PV cells are constructed and arranged so as to provide a desired result. One example of such a result is greater uniformity in the amount of the luminescent radiation received by the different PV cells, for example so that the current generated by each of the PV cells, when the conversion body is uniformly illuminated, is not more than 1.5 times, preferably not more than 1.3 times, particularly not more than 1.1 times, the smallest amount of current generated by any of the PV cells.
   Expedients for achieving a desired result include, for example, the use of PV cells which have at least two different lengths and/or areas exposed to radiation (for example depending upon whether one or both sides of the PV cell are exposed), the length and/or the exposed area being selected so that the amounts of luminescent radiation received by the different PV cells are more closely matched than they would otherwise be.

The invention includes apparatus, methods, conversion bodies, and luminescent bodies which make use of only one of expedients (a)-(e) above, or any combination of two or more of those expedients. The invention will be described chiefly by reference to solar radiation, but the invention includes methods and apparatus in which the radiation is of any wavelength or combination of wavelengths. PV cells as referred to in paragraphs (b) and (c) above are described, for example, in US Patent Publication No. 200502772225, the entire disclosure of which is incorporated by reference herein.

A first preferred aspect of the invention provides apparatus comprising a conversion body which comprises
(1) a luminescent body which
   (i) has a first principal surface which can be exposed to incident spectrum radiation, a second principal surface remote from the first principal surface, and edge surfaces joining the first and second principal surfaces, and
   (ii) comprises luminescent material, the luminescent material, when the first principal surface is exposed to incident spectrum radiation, receiving and absorbing some, but not all, of the incident radiation, and as a result generating luminescent radiation which has a different wavelength from the absorbed radiation, and at least some of which is transmitted to the edge surfaces of the body, and
(2) a plurality of photovoltaic (PV) cells which, when the first principal surface is exposed to incident spectrum radiation and as a result, the luminescent material generates luminescent radiation, (i) receive at least some of the luminescent radiation which is transmitted to the edge surfaces and (ii) convert at least some of the luminescent radiation into electrical energy;
   the apparatus having at least one of the following features, i.e. one only of the following features or any possible combination of two or more of the following features,
(a) the luminescent material is such that, when the first principal surface is exposed to incident radiation, part of the radiation of a selected wavelength range or ranges is absorbed by the luminescent material, thus generating luminescent radiation which is transmitted to the edge surfaces of the luminescent body, and the remainder of the radiation of the selected wavelength range or ranges is transmitted through the luminescent body, the transmitted radiation emerging from the second principal surface;
(b) the luminescent material is such that, when the first principal surface is exposed to incident radiation, at least some of the radiation in first selected wavelength range or ranges of the incident radiation is absorbed by the luminescent material, thus generating luminescent radiation which is transmitted to the edge surfaces of the luminescent body, and at least some of the radiation in second selected wavelength range or ranges of the incident radiation is transmitted, the transmitted radiation emerging from the second principal surface;
(c) at least one of the PV cells is bifacial and is capable of receiving luminescent radiation on both faces;
(d) at least some of the PV cells comprise electrodes which do not cover any substantial part of the face of the PV cell which receives luminescent radiation;
(e) the PV cells have different absorption capacities such that, when the luminescent body is uniformly illuminated, the amounts of current generated by the different PV cells are closer to the same value than they would be if all the PV cells were the same;
(f) The luminescent material is non-uniformly distributed at right angles to the plane of the luminescent body so that at least 50% of the luminescent material lies in a layer or layers constituting at most 30% of the thickness of the body;
(g) The luminescent material is non-uniformly distributed across the plane of the luminescent body, for example so that at least 50% of the luminescent material lies in an area or areas constituting at most 30% of the area of the body.
(h) the amount of luminescent radiation received by each of the PV cells is not more than 1.5 times the smallest amount of luminescent radiation received by any of the PV cells.
(f) the shape of the luminescent body is a regular polyhedron, a rectangle, or includes a regular or irregular curve.

A second preferred aspect of the invention provides a method of generating electrical energy, the method comprising exposing apparatus according to the first preferred aspect of the invention to solar radiation.

A third preferred aspect of the invention provides a luminescent body as defined in the first preferred aspect of the invention and containing luminescent material as defined in paragraph (a), (b), (f) or (g) of the first preferred aspect of the invention.

A fourth preferred aspect of the invention provides a method of preparing a luminescent body as defined in the third preferred aspect of the invention, the method comprising
(a) shaping a liquid composition comprising one or more luminescent materials and a liquid, and then solidifying the composition; or
(b) immersing a sheet of a polymeric material in a liquid solution of one or more luminescent materials so that the luminescent material is absorbed into the sheet; or
(c) adhering a preformed self-supporting layer comprising one or more luminescent materials to a substrate.

When using the invention to transmit a part of the incident radiation, the transmitted radiation can for example be used to illuminate an operation which requires the use of human eyesight, for example reading written material, watching television or a film, operating a machine, e.g. a computer, conducting operations of any kind for business, education or pleasure, e.g. in an office, shop, school, kindergarten, television or radio studio, greenhouse, plant nursery, nursing home or domestic dwelling.

### BRIEF DESCRIPTION OF THE DRAWINGS

The invention is illustrated in the accompanying drawings in which

FIGS. 1-8 are schematic cross-sections, not to scale, of different embodiments of the invention,

FIGS. 9-10 are partial schematic side and top views, not to scale, of another embodiment of the invention, and

FIGS. 11-12 show the spectra of light passing through a simple glass window and through different conversion bodies of the invention.

### DETAILED DESCRIPTION OF THE INVENTION

In the Summary of the Invention above, the Detailed Description of the Invention, the Examples, and the Statements below, and the accompanying drawings, reference is made to particular features of the invention. It is to be understood that the disclosure of the invention in this specification includes all appropriate combinations of such particular features. For example, where a particular feature is disclosed in the context of a particular aspect, a particular embodiment, a particular claim, or a particular Figure, that feature can also be used, to the extent appropriate, in the context of other particular aspects, embodiments, claims and Figures, and in the invention generally.

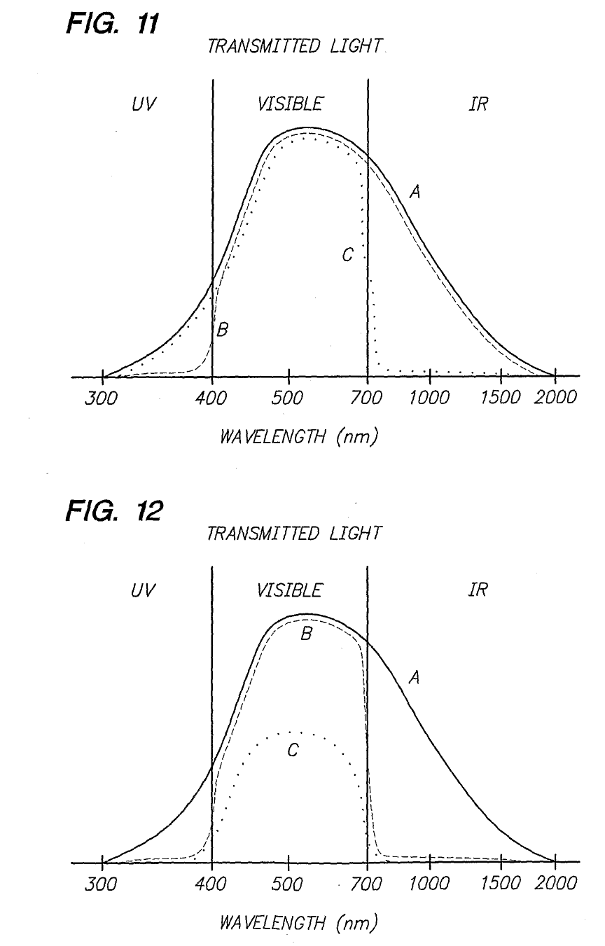

The term “comprises” and grammatical equivalents thereof are used herein to mean that other elements (i.e. components, ingredients, steps etc.) are optionally present. For example, a device “comprising” (or “which comprises”) components A, B and C can contain only components A, B and C, or can contain not only ingredients A, B and C but also one or more other components. The term “consisting essentially of” and grammatical equivalents thereof are used herein to mean that other elements may be present which do not materially alter the invention. Where reference is made herein to a method comprising two or more defined steps, the defined steps can be carried out in any order or simultaneously (except where the context excludes that possibility), and the method can include one or more other steps which are carried out before any of the defined steps, between two of the defined steps, or after all the defined steps (except where the context excludes that possibility. The term “at least” followed by a number is used herein to denote the start of a range beginning with that number (which may be a range having an upper limit or no upper limit, depending on the variable being defined). For example “at least 1” means 1 or more than 1, and “at least 80%” means 80% or more than 80%. The term “at most” followed by a number is used herein to denote the end of a range ending with that number (which may be a range having 1 or 0 as its lower limit, or a range having no lower limit, depending upon the variable being defined). For example, “at most 4” means 4 or less than 4, and “at most 40%” means 40% or less than 40%. When, in this specification, a range is given as “(a first number) to (a second number)” or “(a first number)—(a second number)”, this means a range whose lower limit is the first number and whose upper limit is the second number. The numbers given herein should be construed with the latitude appropriate to their context and expression; for example, each number is subject to variation which depends on the accuracy with which it can be measured by methods conventionally used by those skilled in the art. The terms plural, multiple, plurality and multiplicity are used herein to denote two or more than two items. Where reference is made to absorbing a particular percentage of radiation, the percentage is based on the area of a graph having the wavelength of the radiation on the horizontal X axis and the quantity of radiation on the vertical Y axis (as, for example, in FIGS. 9 and 10). The term “window” is used herein to include windows which form part of a vertical or sloping or horizontal wall or roof, i.e. including skylights, of a building (for example a commercial building, e.g. an office building, hotel, shop or greenhouse; or of a domestic building, e.g. a domestic residence, garage or shed; or of a shelter, e.g. a bus or railroad shelter); windshields on vehicles and boats; and transparent or translucent covers on clocks, watches and other instruments, which may, for example, be partially or completely powered by electricity generated by the PV cells. A window can also be a freestanding article which is not part of a building structure, for example which is placed between the incident radiation and something which will benefit from the modified radiation passing through the window, for example a plant or a mammal.

The invention is particularly useful when the conversion body forms part of a window (as defined above), particularly a window illuminating a room which is habitually occupied by human beings or other animals during daylight hours, and which may be air conditioned. For such use, the conversion body preferably transmits a substantial proportion of the visible light, but absorbs a substantial proportion of either or both of the ultraviolet light and the infrared light, and converts a substantial proportion of the absorbed light into electrical energy. The luminescent material or materials in the conversion body, and the amount or amounts thereof, can be chosen to produce the desired result. Removal of ultraviolet radiation is desirable because it can damage many materials (for example by bleaching them) or be injurious to the health of the occupants of the room. Reduction of infrared radiation is in many cases desirable because infrared radiation causes unwanted heating.

The invention is also useful when the conversion body forms part of a building or other structure comprising a Trombe wall, or other body of large thermal mass, which is heated by solar radiation and which stores the resulting heat for later release. In this case, the conversion body can absorb a substantial proportion of the visible and/or ultraviolet radiation, and convert a substantial proportion of the absorbed radiation into electrical energy, and transmit all or most of the infrared radiation to produce the desired heat.

Suitable luminescent materials which absorb in the infrared range include Nile Blue, Epolight 5548, BASF Lumogen IR 788 and Lumogen IR 765, other substituted dyes of this type, other oligorylenes, and dyes such as DTTC1, Steryl 6, Steryl 7, indocyanine green, IR132, IR144 and IR140. Suitable luminescent materials which absorb in the ultraviolet range include DayGlo Sky Blue (D-286) and Columbia Blue (D-298). Other suitable luminescent materials are disclosed in the documents incorporated by reference herein. The concentration of the luminescent material can be adjusted to give the desired degree of absorbance, for example at least 50%, often at least 70%, or at least 90%, at the frequency of maximum absorbance.

In one method for forming the bodies comprising luminescent materials, a thin layer comprising luminescent materials is secured to a substrate, for example a sheet of glass or a polymeric composition, by coating a liquid composition containing one or more luminescent materials onto the substrate and then solidifying the coating, for example by removing a solvent therefrom or by cooling. In another method, a preformed self-supporting layer comprising one or more luminescent materials is adhered to the substrate. In another method, a sheet, preferably composed of a polymeric composition, is immersed in a liquid solution of one or more luminescent materials so that the luminescent material is absorbed into the sheet.

The embodiments of the invention can optionally have the following features, or any combination of one or more of the following features, except when the features are mutually exclusive. For example, the invention can make use of a combination of features 2 and 3 below, but not a combination of features 3 and 4.

1. The incident radiation is solar radiation.
2. The incident radiation is solar radiation, and the conversion body absorbs a substantial proportion, preferably at least 50%, particularly at least 70%, up to substantially 100% or up to 90%, for example 50-95% or 60-90%, of the ultraviolet light having a wavelength between 300 and 400 nm; and transmits a substantial proportion, preferably at least 40%, particularly at least 60%, especially at least 85%, up to substantially 100% or up to 90%, for example 40-70%, or 60-90%, of the visible light having a wavelength between 400 and 700 nm.
3. The incident radiation is solar radiation, and the conversion body absorbs a substantial proportion, preferably at least 50%, particularly at least 70%, up to substantially 100% or up to 90%, for example 50-95% or 60-90%, of the infrared light having a wavelength between 700 and 2000 nm; and transmits a substantial proportion, preferably at least 5%, particularly at least 15%, especially at least 85%, up to substantially 100% or up to 90%, for example 5-40%, or 15-90%, of the visible light having a wavelength between 400 and 700 nm.
4. The incident radiation is solar radiation; the conversion body absorbs a substantial proportion, preferably at least 50%, particularly at least 70%, up to substantially 100% or up to 90%, for example 50-95% or 60-90%, of the visible light having a wavelength between 400 and 700 nm and/or absorbs a substantial proportion, preferably at least 50%, particularly at least 70%, up to substantially 100% or up to 90%, for example 50-95% or 60-90%, of the ultraviolet light having a wavelength between 300 and 400 nm.; and transmits a substantial proportion, preferably at least 40%, particularly at least 60%, especially at least 85%, up to substantially 100% or up to 90%, for example 40-70%, or 60-90%, of the infrared light having a wavelength between 700 and 2000 nm.
5. A substantial proportion, preferably at least 20%, more preferably at least 30%, particularly at least 50%, especially at least 75%, of the luminescent radiation is received by a PV cell.
6. The luminescent material removes selected portions of the visible light spectrum, so that the light passing through the window has a desired color.
7. The conversion body comprises a frame which surrounds the luminescent body or bodies. The frame may be made, for example, of wood or metal or a polymeric composition, so that the conversion body can be incorporated into a building or other structure, for example so as to provide a window (as defined above) which permits visible light to enter the structure. The frame can protect the PV cells. It can also incorporate, and/or provide a housing for, wiring so that the PV cells are connected in series and/or in parallel, for example so that some or all of the desired electrical connections are made when the luminescent body or bodies is/are inserted into the frame. The frame can comprise mechanical features which permit it to be secured to the building, for example a nailing flange and/or holes through which screws or nails can be passed. The size of the window can range from quite small to very large; for example the window may have an area corresponding to dimensions as small as 5 cm×5 cm or as large as 4 m×6 m, i.e. 25 cm² to 24 m², e.g. from 0.5 to 5 m².
8. The conversion body is fitted over the inside or the outside of an existing window, leaving a gap between the conversion body and the existing window. The conversion body can be secured, optionally sealed, to the existing window or its frame, in which case the gap can optionally be under partial vacuum and/or the air in the gap be replaced by another gas, for example an inert gas. In one embodiment, the conversion body is removably secured to the existing window and/or its frame, so that the conversion body can be removed in order to clean the conversion body and/or the existing window.
9. The conversion body comprises two or more laminar members, one or more of the laminar members being a luminescent body. The laminar members can be laminated directly to each other, in a manner similar to two or more layers of glass in a laminated glass structure; and/or can be separated from each other by a space which optionally is under partial vacuum and/or is filled with a gas, for example an inert gas; and/or can be separated from each other by a transparent filler layer, for example a layer of a polymeric composition. The conversion body can be, for example, a window pane suitable for use in a thermally insulated window, or a thermally insulated window in which the two or more laminar members are surrounded by a frame, for example as set out in feature 7 above. In an example of such a structure, one of the laminar members is a luminescent body which transmits visible light and another laminar member is a different type of luminescent body, or a conventional sheet of glass. In another such structure, each of the laminar members is a conversion body of the invention which transmits visible light.
10. The conversion body comprises (1) an optically transparent substrate, e.g. a sheet of glass or a polymeric composition (i.e. a composition which comprises a polymer and which optionally contains conventional additives), which is relatively thick, e.g. 0.1 to 0.5 inch (2.5 to 12.5 mm) thick, and (2) a relatively thin luminescent body, e.g. 0.001 to 0.2 inch (0.025 to 5 mm), for example 0.01 to 0.1 inch (0.25 to 2.5 mm), thick, which is adherent to the surface of the substrate and which comprises one or more luminescent materials. In one embodiment, the luminescent material is dispersed in a matrix, e.g. a matrix of a polymeric composition. There can be two or more such relatively thin luminescent bodies, on the same or on opposite sides of the substrate, containing the same or different luminescent materials. In use, the luminescent body or bodies comprising the luminescent material can for example be the first surface of the conversion body struck by the incident radiation or an intermediate surface of the conversion body.
11. The conversion body comprises a self-supporting luminescent body, for example 0.01 to 1.0 inch (0.25 to 25 mm), e.g. 0.1 to 0.5 inch (2.5 to 12.5 mm) thick, which comprises a transparent matrix material, e.g. a polymeric composition, and, dispersed in the matrix material (uniformly or in a desired pattern) one or more luminescent materials. There can be two or more such self-supporting luminescent bodies, containing the same or different luminescent materials.
12. The conversion body is laminar, for example planar or has a shape which is smoothly curved in two dimensions.
13. The edge surfaces define the outer periphery of the principal surfaces and/or an inner periphery of principal surfaces having one or more holes therein.
14. The luminescent radiation passes directly into the PV cells, or is treated, for example to concentrate it, before it reaches the PV cells, for example as described in the patents incorporated by reference herein.
15. At least one of the PV cells, for example each of the PV cells, is bifacial, i.e. will generate electricity in response to radiation from both sides. Such cells are described, for example, in US Patent Publication No. 200502772225, the entire disclosure of which is incorporated by reference herein. Some or all of the PV cells can be bifacial. Bifacial PV cells can be used along the periphery of solar collection device, for example a luminescent body, which is at the edge of a conversion body, in which case only one face of the PV cell will receive radiation. Bifacial PV cells can also be used between two solar collection devices so that each side of the PV cell receives radiation, one or both of the solar collection devices being for example a luminescent body.
16. At least one of the PV cells, for example each of the PV cells, comprises electrodes which do not cover any substantial part of the face(s) of the PV cell which receives luminescent or other radiation. The PV cell can, for example, have a rectangular cross-section with relatively narrow top and bottom surfaces which carry ohmic electrodes and relatively wide surfaces which are exposed to the radiation. The use of such PV cells not only increases the absorption efficiency, but also makes it easier to make the electrical connection of such PV cells to each other, in series or in parallel as desired, as compared to PV cells which carry electrodes on the surfaces which are exposed to the radiation. Their use also facilitates the construction and use of conversion bodies which comprise a plurality of luminescent bodies or other collection devices (usually coplanar devices) within a frame surrounding the plurality of conversion bodies. PV cells fitted with the electrodes of this kind are disclosed in US Patent Publication No. 200502772225, incorporated by reference herein.
17. The luminescent body or other collection device is fitted with PV cells having different absorption abilities, the difference being selected with the aim of reducing the differences between, preferably substantially equalizing, the electrical current generated within the different PV cells. In this way, it is possible to compensate for the fact that the internal reflection of the radiation can result in differences in the radiation reaching the edges of the conversion body. One convenient way of obtaining PV cells with different absorption abilities is to make use of PV cells which have different lengths, but which are otherwise the same. The use of such cells makes it possible to make use of a larger proportion of a conventional PV cell which is divided into slices. For example, US Patent Publication No. 200502772225 discloses such division, but only for the production of PV cells of uniform length. This invention includes a process in which such division is made over a wider area of the silicon wafer, resulting in PV cells having different lengths. It is also possible, additionally or alternatively, to make use of PV cells whose exposed faces have different areas for some additional reason, or which are composed of materials having different absorption abilities. For example, the PV cells can be selected so that the current generated in each of the PV cells is not more than 1.50 times, preferably not more than 1.3 times, particularly not more than 1.1 times, the smallest current generated by any of the PV cells.
18. At least one of the PV cells, for example each of the PV cells, is composed of silicon, or one of the other materials known for use in PV cells. The whole of the silicon (or other material) can be doped, or part can be intrinsic or otherwise undoped. For example, silicon adjacent to the surface or surfaces of the PV cell which are exposed to the luminescent radiation can be doped, and the interior of the silicon body can be undoped.
19. The shape of the luminescent or other absorption body is a triangle, rectangle (including a square) or other regular polyhedron, particularly a shape which enables a plurality of similarly shaped bodies to be fitted together without any gaps between them, and/or which causes the current generated in each of the PV cells to be not more than 1.50 times, preferably not more than 1.3 times, particularly not more than 1.1 times, the smallest current generated by any of the PV cells. It is also possible for the invention to make use of a plurality of luminescent or other absorption or transmission (e.g. clear or colored glass or polymeric composition) which have different shapes, for example shapes which can be fitted together in a pattern with no gaps between the bodies.
20. The conversion body comprises a plurality of luminescent or other absorption or transmission bodies, which can be substantially the same, or which can differ in one or more of their composition, shape, area, thickness and response to radiation. The bodies can be selected to provide a desired functional or decorative purpose, for example a purpose which varies with the wavelength and/or angle of the incident radiation.

### The Drawings.

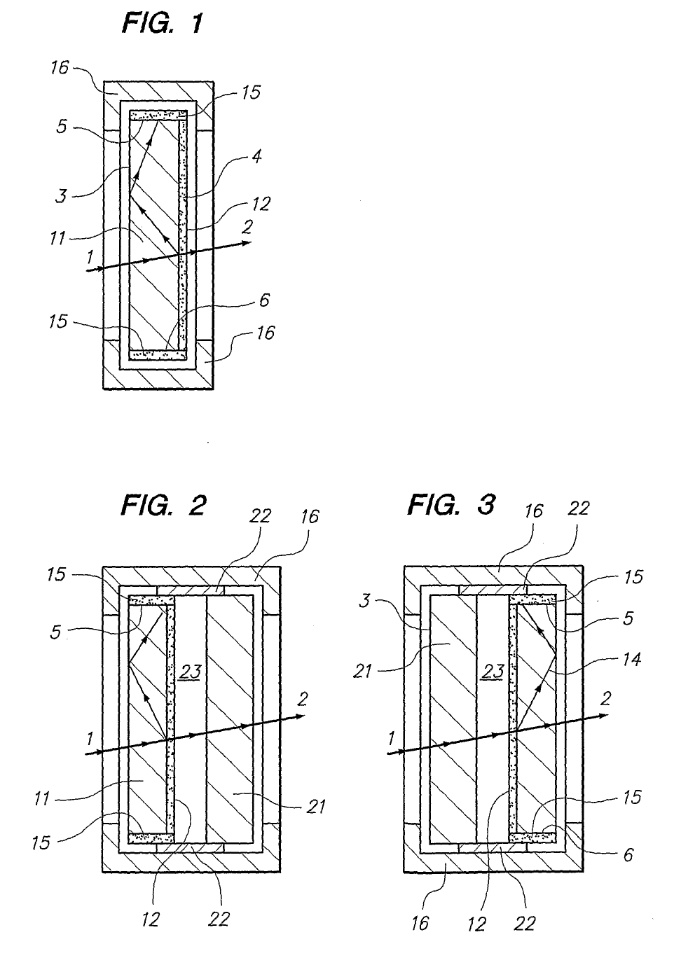

Referring now to the drawings, FIG. 1 shows a conversion body comprising (a) a transparent glass member 11 which provides a first principal surface 3 exposed to incident sunlight 1; (b) a luminescent body 12 which is adherent to the member 11 and which comprises luminescent material (shown schematically as dots), and which provides a second principal surface 4; and (c) PV cells 15 at the edge surfaces 5, 6 of the glass member 11 and luminescent body 12. The conversion body is surrounded by a frame 16. The luminescent material absorbs part of the incident sunlight, and as a result generates luminescent radiation. At least some of the luminescent radiation is transmitted to the PV cells by reflection within and/or between the member 11 and the luminescent body 12. The remainder of the incident sunlight emerges from the second principal surface as radiation 2.

FIG. 2 shows a conversion body which contains components 11, 12 and 15 as in FIG. 1, and also a laminar glass member 21 which is secured, optionally sealed, to the remainder of the conversion body by a member 22, but separated from the remainder of the conversion body by a gap 23 which optionally is evacuated and/or filled with a suitable gas, for example an inert gas. The frame 16 is thicker than in FIG. 1.

FIG. 3 has the same components as FIG. 2, except that the incident sunlight passes through the laminar glass member 21 before it passes through the luminescent body 12.

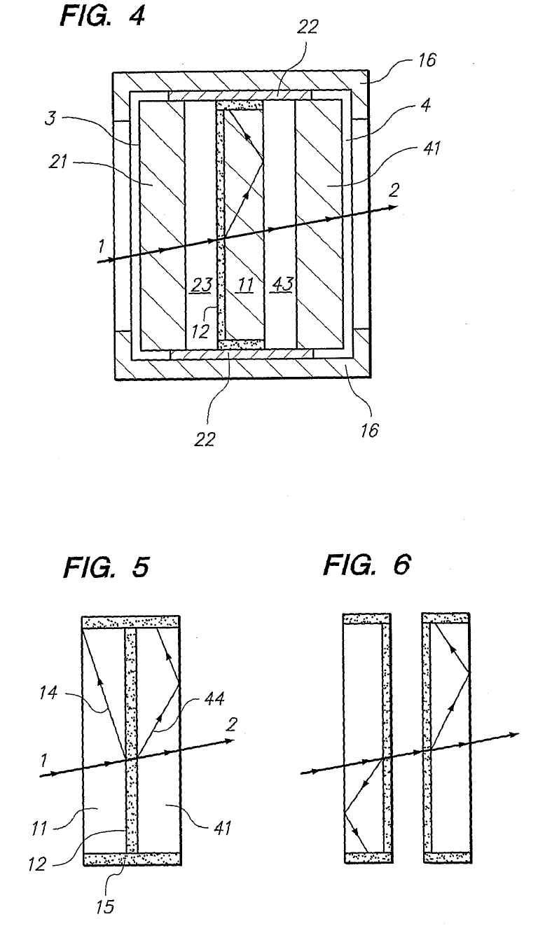

FIG. 4 has the same components as FIG. 3 and in addition a second laminar glass member 41 which is attached, optionally sealed, to the remainder of the conversion body by the member 22, but separated from the remainder of the conversion body by a gap 43 which is evacuated and/or filled with a suitable gas, for example an inert gas. The frame 16 is larger than in FIG. 3.

FIG. 5 shows a conversion body which is similar to the conversion body shown in FIG. 1, but which also comprises a second laminar glass member 41 which contacts the opposite side of the layer 12. The PV cells extend over the edges of the second glass member 41. At least some of the luminescent radiation is transmitted to the PV cells by reflection 14 within and/or between the members 11 and 41 and the luminescent body 12.

FIG. 6 shows an arrangement of two conversion bodies, each of which is the same as the conversion body in FIG. 1, and which are placed with the layers 12 adjacent to each other.

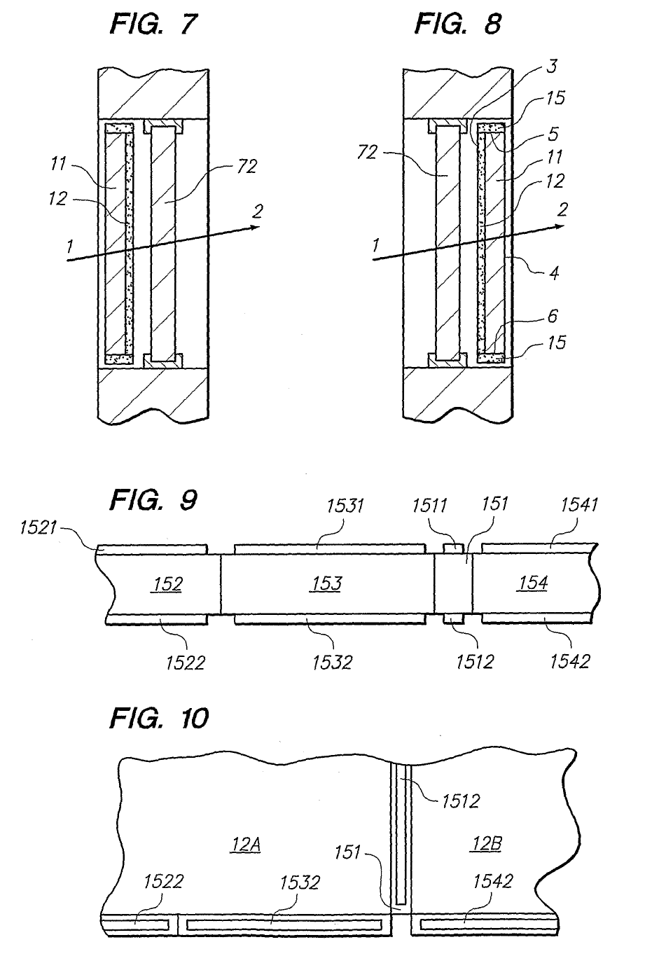

FIGS. 7 and 8 show arrangements in which a conversion body as shown in FIG. 1 is fitted to the outside (FIG. 7) or to the inside (FIG. 8) of existing window 72.

FIGS. 9 and 10 are partial top and a side views of a conversion body comprising two luminescent bodies 12A and 12B, bifacial PV cell 151 which receives luminescent radiation from each of the luminescent bodies 12A and 12B, PV cells 152 and 153 on an exposed edge of the luminescent body 12A, and PV cell 154 on an exposed edge of the luminescent body 12B. Each of the PV cells includes top ohmic electrodes 1511, 1521 . . . and bottom ohmic electrodes 1512, 1522 . . . .

FIG. 11 is a graph of the spectrum (solid curve A) of the light passing through a normal glass window, showing the infrared (IR), visible, and ultraviolet (UV) regions; the spectrum of light passing through a conversion body of the invention designed to absorb a substantial proportion of the ultraviolet radiation and to transmit visible and infrared light (dashed curve B); and a conversion body of the invention designed to absorb a substantial proportion of the infrared radiation and to transmit visible and ultraviolet light (dotted curve C).

FIG. 12 is a graph of the spectrum (solid curve A) of the light passing through a normal glass window, showing the infrared (IR), visible, and ultraviolet (UV) regions; the spectrum (dashed curve B) of light passing through a first conversion body of the invention which is designed to absorb a substantial proportion of the infrared and ultraviolet radiation and to transmit substantially all of the visible light; and the spectrum (dashed curve C) of light passing through a second conversion body of the invention which is designed to absorb a substantial proportion of the infrared and ultraviolet radiation, and some, but not all, of the visible light.

### EXAMPLES

The invention is illustrated by the following Examples.

### Example 1

A luminescent body suitable for use as a window pane was produced by immersing a piece of polymethylmethacrylate (PMMA) for 6 hours in a solution of BASF Red Lumogen Dye in a mixture of toluene and methanol (1:6). Optical measurements of the product demonstrated significant transmission in the visible range, with an absorption peak near 570 nm.

### Example 2

A luminescent body suitable for use as a window pane was produced by immersing a piece of PMMA for 15 hours in a solution of Nile Blue Dye in a mixture of toluene and methanol (1:7). Optical measurements of the product demonstrated significant transmission in the visible range, with an absorption peak near 628 nm.

### Example 3

Example 2 was repeated, replacing the Nile Blue Dye by BASF Lumogen IR 788 dye. The absorption spectrum of the resulting luminescent body shows broad and strong absorption in the infrared region, peaking at about 750 nm, with appreciable transmission of visible light.

### Example 4

Another example of a luminescent body suitable for use as a window pane was produced by immersing a piece of PMMA for 6 hours in a solution of Epolight 5548 Dye in a mixture of methylene chloride and methanol (1:7). The transmission spectrum of the luminescent body shows broad and strong absorption in the infrared region, peaking at about 750 nm, with appreciable transmission of visible light.

### Example 5

Another example of a luminescent body suitable for use as a window pane was produced by (1) dissolving 10 g PMMA in 100 ml methylene chloride; (2) dissolving 100 mg DayGlo dye D149 into 10 ml methylene chloride; (3) mixing these two solutions; and (4) spreading the mixture onto a piece of glass and letting the mixture dry. The result was a uniform coating with a strong red color and strong fluorescence. The optical density was 1.7 at the peak absorption near 548 nm.

### Example 6

The dried coating prepared in Example 5 was peeled off the glass, giving a freestanding film about 125 micron in thickness. The film showed fluorescence at its edges. The film was placed on the surface of a piece of clear glass with a small quantity of oil at the interface to make optical contact. The fluorescence appeared at the edges of the glass substrate.

### Example 7

Another example of a luminescent body suitable for use as a window pane was produced by (1) dissolving 10 g PMMA in 200 ml toluene; (2) dissolving 350 mg BASF Red 300 Lumigen Dye in 100 mm of toluene; (3) mixing these two solutions; and (4) spreading the mixture onto a piece of glass (about 215×250 mm) and letting the mixture dry. The result was a uniform coating with a strong adherence to the glass.

1. Apparatus which comprises
(1) a luminescent body which
(i) has a first principal surface which can be exposed to incident spectrum radiation, a second principal surface remote from the first principal surface, and edge surfaces joining the first and second principal surfaces,
(ii) comprises luminescent material which, when the first principal surface is exposed to incident solar radiation, absorbs some, but not all, of the incident radiation, and generates luminescent radiation which has a different wavelength from the absorbed radiation, at least some of the luminescent radiation passing to the edge surfaces of the body, and
(iii) when the first principal surface is exposed to incident solar radiation, transmits some, but not all, of the incident radiation so that it emerges from the second principal surface; and
(2) a plurality of photovoltaic (PV) cells which, when the first principal surface of the luminescent body is exposed to incident solar radiation and luminescent radiation passes to the edge surfaces of the luminescent body, (i) receive at least some of the luminescent radiation which passes to the edge surfaces and (ii) convert the received luminescent radiation into electrical energy.

2. A method of generating electrical energy, the method comprising exposing apparatus as defined in claim 1 to solar radiation.

3. (canceled)

4. (canceled)

5. Apparatus according to claim 1 wherein, when the first principal surface is exposed to incident solar radiation, the luminescent material absorbs part of the incident radiation of a selected wavelength range or ranges, and the remainder of the incident radiation of the selected wavelength range or ranges is transmitted through the luminescent body and emerges from the second principal surface.

6. Apparatus according to claim 1 wherein, when the first principal surface is exposed to incident solar radiation, the luminescent material absorbs at least some of the incident radiation of a first selected wavelength range or ranges, and at least some of the radiation in a second selected wavelength range or ranges of the incident radiation is transmitted through the luminescent body and emerges from the second principal surface.

7. Apparatus according to claim 1 wherein the PV cells have different absorption capacities such that, when the luminescent body is uniformly illuminated, the current generated by each of the PV cells is not more than 1.5 times the smallest current generated by any of the PV cells.

8. Apparatus according to claim 1 wherein at least 50% of the luminescent material lies in a layer or layers constituting at most 30% of the thickness of the body.

9. Apparatus according to claim 1 wherein at least one of the PV cells is bifacial and, when the apparatus is exposed to incident solar radiation, receives luminescent radiation on both faces.

10. Apparatus according to claim 1 which is a window and which, when exposed to solar radiation, (i) transmits a substantial proportion of visible light and (ii) absorbs and converts into electrical energy a substantial proportion of either or both of ultraviolet light and infrared light.

11. Apparatus according to claim 10 wherein the luminescent body is planar and which further comprises at least one optically transparent planar member which is composed of glass or a polymeric composition.

12. Apparatus according to claim 11 which, when exposed to solar radiation, absorbs at least 70% of the ultraviolet light having a wavelength between 300 and 400 nm, and transmits at least 60% of the visible light having a wavelength between 400 and 700 nm.

13. Apparatus according to claim 11 which, when exposed to solar radiation, absorbs at least 70% of the infrared light having a wavelength between 700 and 2000 nm and transmits at least 15% % of the visible light having a wavelength between 400 and 700 nm.

14. Apparatus according to claim 11 which, when exposed to solar radiation, absorbs at least 70% of the ultraviolet light having a wavelength between 300 and 400 nm, and transmits at least 60% of the visible light having a wavelength between 400 and 700 nm.

15. Apparatus which comprises
(1) a luminescent body which
(i) has a first principal surface which can be exposed to incident spectrum radiation, a second principal surface remote from the first principal surface, and edge surfaces joining the first and second principal surfaces,
(ii) comprises luminescent material which, when the first principal surface is exposed to incident solar radiation, absorbs some, but not all, of the incident radiation and generates luminescent radiation which has a different wavelength from the absorbed radiation, at least some of the luminescent radiation passing to the edge surfaces of the body, and at least 50% of the luminescent material being in a layer or layers constituting at most 30% of the thickness of the body, and
(iii) when the first principal surface is exposed to incident solar radiation, transmits some, but not all, of the incident radiation so that it emerges from the second principal surface; and
(2) a plurality of photovoltaic (PV) cells which, when the first principal surface of the luminescent body is exposed to incident solar radiation and luminescent radiation passes to the edge surfaces of the luminescent body, (i) receive at least some of the luminescent radiation which passes to the edge surfaces and (ii) convert the received luminescent radiation into electrical energy; the PV cells having different lengths such that, when the luminescent body is uniformly illuminated, the current generated by each of the PV cells is not more than 1.3 times the smallest current generated by any of the PV cells.

16. Apparatus according to claim 15 wherein, when the first principal surface is exposed to incident solar radiation, the luminescent material absorbs part of the incident radiation of a selected wavelength range or ranges, and the remainder of the incident radiation of the selected wavelength range or ranges is transmitted through the luminescent body and emerges from the second principal surface.

17. Apparatus according to claim 15 wherein, when the first principal surface is exposed to incident solar radiation, the luminescent material absorbs at least some of the incident radiation of a first selected wavelength range or ranges, and at least some of the radiation in a second selected wavelength range or ranges of the incident radiation is transmitted through the luminescent body and emerges from the second principal surface.

18. Apparatus according to claim 15 wherein at least one of the PV cells is bifacial and, when the apparatus is exposed to incident solar radiation, receives luminescent radiation on both faces.

19. Apparatus according to claim 15 wherein, when the luminescent body is uniformly illuminated, the current generated by each of the PV cells is not more than 1.1 times the smallest current generated by any of the PV cells.

20. Apparatus as defined in paragraphs (1) and (2) below, as further restricted by one or more of the alternatives of paragraphs (a) to (i) below; luminescent bodies containing luminescent material as defined in one or more of paragraphs (a), (b), (f) and (g) below; and methods of preparing such luminescent bodies;
(1) a luminescent body which
(i) has a first principal surface which can be exposed to incident spectrum radiation, a second principal surface remote from the first principal surface, and edge surfaces joining the first and second principal surfaces, and
(ii) comprises luminescent material, the luminescent material, when the first principal surface is exposed to incident spectrum radiation, receiving and absorbing some, but not all, of the incident radiation, and as a result generating luminescent radiation which has a different wavelength from the absorbed radiation, and at least some of which is transmitted to the edge surfaces of the body, and
(2) a plurality of photovoltaic (PV) cells which, when the first principal surface is exposed to incident spectrum radiation and as a result, the luminescent material generates luminescent radiation, (i) receive at least some of the luminescent radiation which is transmitted to the edge surfaces and (ii) convert at least some of the luminescent radiation into electrical energy; the apparatus having at least one of the following features
(a) the luminescent material is such that, when the first principal surface is exposed to incident radiation, part of the radiation of a selected wavelength range or ranges is absorbed by the luminescent material, thus generating luminescent radiation which is transmitted to the edge surfaces of the luminescent body, and the remainder of the radiation of the selected wavelength range or ranges is transmitted through the luminescent body, the transmitted radiation emerging from the second principal surface;
(b) the luminescent material is such that, when the first principal surface is exposed to incident radiation, at least some of the radiation in first selected wavelength range or ranges of the incident radiation is absorbed by the luminescent material, thus generating luminescent radiation which is transmitted to the edge surfaces of the luminescent body, and at least some of the radiation in second selected wavelength range or ranges of the incident radiation is transmitted, the transmitted radiation emerging from the second principal surface;
(c) at least one of the PV cells is bifacial and is capable of receiving luminescent radiation on both faces;
(d) at least some of the PV cells comprise electrodes which do not cover any substantial part of the face of the PV cell which receives luminescent radiation;
(e) the PV cells have different absorption capacities such that, when the luminescent body is uniformly illuminated, the amounts of current generated by the different PV cells are closer to the same value than they would be if all the PV cells were the same;
(f) The luminescent material is non-uniformly distributed at right angles to the plane of the luminescent body so that at least 50% of the luminescent material lies in a layer or layers constituting at most 30% of the thickness of the body;
(g) The luminescent material is non-uniformly distributed across the plane of the luminescent body, for example so that at least 50% of the luminescent material lies in an area or areas constituting at most 30% of the area of the body.
(h) the amount of luminescent radiation received by each of the PV cells is not more than 1.5 times the smallest amount of luminescent radiation received by any of the PV cells.
(i) the shape of the luminescent body is a regular polyhedron, a rectangle, or includes a regular or irregular curve.
